(19) United States
(12) Patent Application Publication
(10) Pub. No.: US 2025/0140509 A1
(43) Pub. Date: May 1, 2025

(54) ION NEUTRALIZATION MODULE

(71) Applicant: Samsung Electronics Co., Ltd., Suwon-si (KR)

(72) Inventors: Dongwan KIM, Suwon-si (KR); Minsung KIM, Suwon-si (KR); Youngseok SONG, Suwon-si (KR); Jisoo IM, Suwon-si (KR); Kanghee KIM, Suwon-si (KR); Younseon WANG, Suwon-si (KR); Junho IM, Suwon-si (KR)

(73) Assignee: Samsung Electronics Co., Ltd., Suwon-si (KR)

(21) Appl. No.: 18/631,735

(22) Filed: Apr. 10, 2024

(30) Foreign Application Priority Data
Oct. 27, 2023 (KR) 10-2023-0145236

(51) Int. Cl. H01J 37/02; H01J 37/305

(52) U.S. Cl. CPC H01J 37/026; H01J 37/3053; H01J 2237/0041

(57) ABSTRACT

An ion neutralization module comprising a reflector configured to neutralize an ion, a frame configured to support the reflector, and a conductive adhesive between the reflector and the frame to attach the reflector to the frame.

### CROSS-RELATED APPLICATION

This application claims priority under 35 USC § 119 to Korean Patent Application No. 10-2023-0145236, filed on Oct. 27, 2023 in the Korean Intellectual Property Office (KIPO), the contents of which are herein incorporated by reference in their entirety.

### BACKGROUND

Various example embodiments relate to an ion neutralization module. More particularly, various example embodiments relate to an ion neutralization module configured to neutralize an ion in an ion beam apparatus.

In an etching apparatus using an ion beam, an ion neutralization module may neutralize the ion beam using a reflector to form a neutral beam. The neutral beam may be applied to a substrate and to each a layer on the substrate.

According to related arts, the reflector may have an integral type structure. The ion beam may strongly collide against the integral type reflector, thus generating contaminants from the reflector. Further, the reflector may be thermally deformed or a surface roughness of the reflector may be changed at a high temperature so that neutralization efficiency of the reflector may be decreased. Furthermore, when the reflector includes a metal, certain kinds of reaction gases may be restricted.

### SUMMARY

Various example embodiments provide an ion neutralization module that may be capable of suppressing the generation of contaminants, preventing thermal deformation of the reflectors, and preventing changes in surface roughness of the reflectors at a high temperature. Furthermore, various example embodiments may provide an ion neutralization module with less restriction of available reaction gases.

According to various example embodiments, there may be provided an ion neutralization module comprising a reflector configured to neutralize an ion, a frame configured to support the reflector, and a conductive adhesive between the reflector and the frame to attach the reflector to the frame.

According to various example embodiments, there may be provided an ion neutralization module comprising a reflector including a plurality of blades configured to neutralize an ion, a frame configured to support an outer circumferential surface of the reflector and to receive a refrigerant, the frame including a material different from a material of the reflector, and a conductive adhesive interposed between the reflector and the frame to attach the reflector to the frame, the conductive adhesive configured to allow electron transportation and further configured to prevent leakage of the refrigerant. The frame comprises an upper frame configured to fix the reflector, and a lower frame combined with the upper frame.

According to various example embodiments, there may be provided an ion neutralization module comprising a plurality of blades configured to neutralize an ion, a blade ring configured to fix both ends of the plurality of the blades, a frame arranged under the blade ring, the frame including a material different from a material of the plurality of the blades; and a heat transfer type adhesive pad interposed between the blade ring and the frame to attach the blade ring to the frame. The frame comprises an upper frame configured to fix a reflector, and a lower frame combined with the upper frame.

According to various example embodiments, the ion neutralization module may include the detachable reflector and the frame so that optimal materials suitable for a semiconductor process may be applied to the reflector and the frame. Thus, the generation of contaminants from the reflector may be suppressed. Furthermore, thermal deformation and/or a change of a surface roughness of the reflectors at a high temperature may also be suppressed. As a result, the reflector may have improved neutralization efficiency.

### BRIEF DESCRIPTION OF THE DRAWINGS

Various example embodiments will be more clearly understood from the following detailed description taken in conjunction with the accompanying drawings. FIGS. 1 to 7 represent non-limiting, various example embodiments as described herein.

FIG. 1 is a cross-sectional view illustrating an apparatus for processing a substrate in accordance with various example embodiments;

FIG. 2 is an exploded perspective view illustrating an ion neutralization module of the apparatus in FIG. 1;

FIG. 3 is a perspective view illustrating the ion neutralization module in FIG. 2;

FIG. 4 is a cross-sectional view illustrating the ion neutralization module in FIG. 3;

FIG. 5 is an enlarged cross-sectional view of a portion “A” in FIG. 4;

FIG. 6 is an exploded perspective view illustrating an ion neutralization module in accordance with various example embodiments; and

FIG. 7 is a perspective view illustrating an ion neutralization module in accordance with various example embodiments.

### DETAILED DESCRIPTION OF THE EMBODIMENTS

Hereinafter, various example embodiments will be explained in detail with reference to the accompanying drawings.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C, or any combination thereof. Likewise, A and/or B means A, B, or A and B.

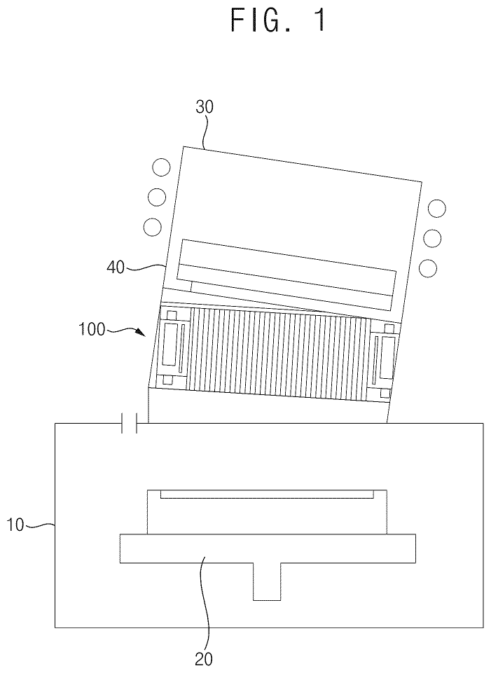

FIG. 1 is a cross-sectional view illustrating an apparatus for processing a substrate in accordance with various example embodiments.

Referring to FIG. 1, an apparatus for processing a substrate may be configured to etch a substrate, particularly, to etch a semiconductor substrate using a neutral beam. The apparatus may include a reaction chamber 10, a stage 20, a plasma generator 30, a grid array 40 and an ion neutralization module 100.

The reaction chamber 10 may be configured to receive the semiconductor substrate. The stage 20 may be placed on a bottom surface of the reaction chamber 10. The semiconductor substrate may be placed on an upper surface of the stage 20.

The plasma generator 30 may be arranged over the reaction chamber 10. The plasma generator 30 may generate plasma. The grid array 40 may be arranged between the plasma generator 30 and the reaction chamber 10. The grid array 40 may be arranged inclined to a vertical direction. The plasma generated from the plasma generator 30 may be introduced into the reaction chamber 10 through the grid array 40.

The ion neutralization module 100 may be arranged between the grid array 40a and the reaction chamber 10. The ion neutralization module 100 may convert ions in the plasma into the neutral beams.

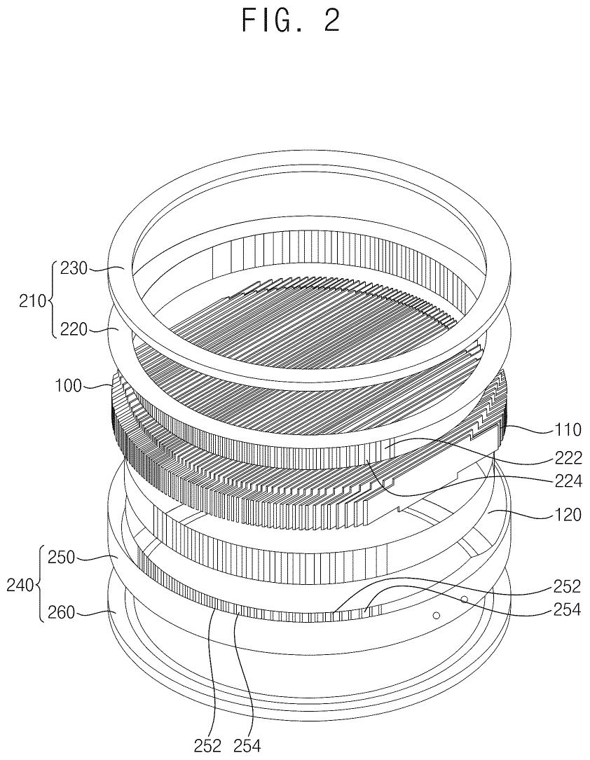

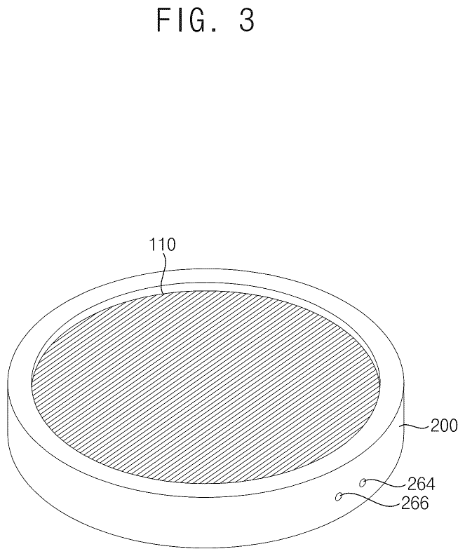

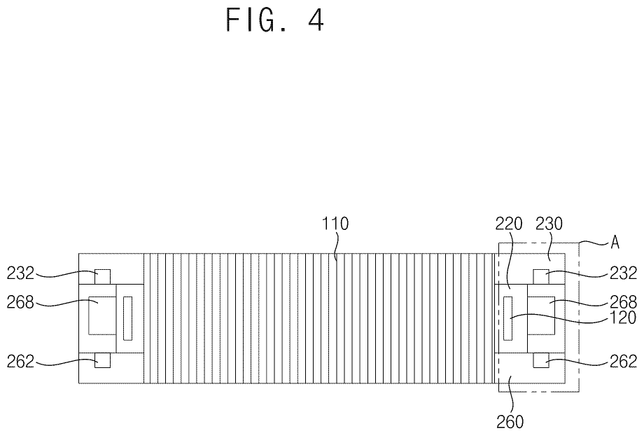

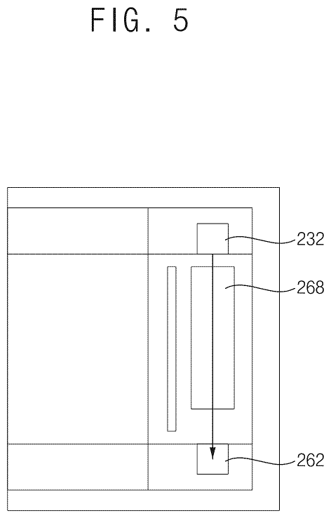

FIG. 2 is an exploded perspective view illustrating an ion neutralization module of the apparatus in FIG. 1, FIG. 3 is a perspective view illustrating the ion neutralization module in FIG. 2, FIG. 4 is a cross-sectional view illustrating the ion neutralization module in FIG. 3 and FIG. 5 is an enlarged cross-sectional view of a portion “A” in FIG. 4.

Referring to FIGS. 2 to 5, the ion neutralization module 100 may include a reflector 110, a frame 200 and a conductive adhesive 120.

The reflector 110 may reflect the ions to neutralize the ions. In various example embodiments, the reflector 110 may include a plurality of blades 112. In order to direct the neutral beam to the semiconductor substrate along the vertical direction, the blades 112 may be slanted in the vertical direction at an angle narrower than an inclined angle of the grid array 40. For example, the inclined angle of the blades 112 may be a half of the inclined angle of the grid array 40, but not limited thereto. Further, the blades 112 may be spaced apart from each other by a substantially uniform gap along a horizontal direction, but not limited thereto. The blades 112 may be arranged in a circular plate, but not limited thereto.

In various example embodiments, the reflector 110 may include a conductive material for supplying the electrons to neutralize the ions. Particularly, the reflector 110 may include a conductive material selected for decreasing contaminants generated by sputtering from an ion beam. For example, the reflector 110 may include silicon, silicon carbide, etc., but example embodiments are not limited thereto.

The frame 200 may be configured to support the reflector 110 to determine a position of the reflector 110. That is, the blades 112 may be fixed to the frame 200. Because the blades 112 may have the circular plate shape, the frame 200 may have an annular shape configured to receive the blades 112.

In various example embodiments, the frame 200 may include a material different from the material of the reflector 110. The material of the frame 200 may have good heat transfer efficiency. Further, the material of the frame 200 may have a low thermal strain. For example, the frame 200 may include a metal such as at least one of molybdenum, tungsten, etc., but example embodiments are not limited thereto. Further, the frame 200 may include a cooling passage through which a refrigerant for the heat transfer may flow.

The frame 200 may include an upper frame 210 and a lower frame 240. The upper frame 210 may be configured to fix the reflector 110. Particularly, both ends of the blades 112 may be fixed to an inner circumferential surface of the upper frame 210. The lower frame 240 may be combined with the upper frame 210. The lower frame 240 may be detached from the upper frame 210.

The upper frame 210 may include an upper guide 220 and an upper cover 230. The upper guide 220 may be configured to support an outer circumferential surface of the reflector 110. The upper cover 230 may be arranged on an upper surface of the upper guide 220. The upper cover 230 may include an upper cooling passage 232 through which the refrigerant may flow.

Particularly, the upper guide 220 may have an annular shape. Because the reflector 110 may be received in the upper guide 220, the upper guide 220 may have a diameter slightly longer than a diameter of the reflector 110. The upper guide 220 may include a plurality of upper combination grooves 222. The upper combination grooves 222 may be formed on an outer circumferential surface of the upper guide 220 in the vertical direction. Particularly, the upper combination grooves 222 may be upwardly formed from a lower end of the upper guide 220. The upper combination grooves 222 may be spaced apart from each other by a substantially uniform gap. Thus, a plurality of upper combination protrusions 224 may be formed between the upper combination grooves 222.

The upper cover 230 may have an annular shape. The upper cover 230 may have a diameter substantially the same as the diameter of the upper guide 220. The upper cooling passage 232 may be formed at the upper cover 230. Particularly, the upper cooling passage 232 may be formed on a lower surface of the upper cover 230 along a circumferential direction of the upper cover 230. That is, a lower surface of the upper cooling passage 232 may be downwardly exposed. When the upper cover 230 may be combined with the upper guide 220, the upper surface of the upper guide 220 may make contact with the lower surface of the upper cover 230. Thus, the lower surface of the upper cooling passage 232 may correspond to the upper surface of the upper guide 220.

The lower frame 240 may include a lower guide 250 and a lower cover 260. The lower guide 250 may be configured to receive the upper guide 220 of the upper frame 210. The lower cover 260 may be arranged on a lower surface of the lower guide 250. The lower cover 260 may include a lower cooling passage 262 through which the refrigerant may flow.

Particularly, the lower guide 250 may have an annular shape. Because the upper guide 220 may be received in the lower guide 250, the lower guide 250 may have a diameter slightly longer than the diameter of the upper guide 220. Particularly, an inner circumferential surface of the lower guide 250 may make contact with the inner circumferential surface of the upper guide 220. Thus, an inner diameter of the lower guide 250 may be substantially the same as an outer diameter of the upper guide 220.

Further, the lower guide 250 may include a plurality of lower combination grooves 252. The lower combination grooves 252 may be formed on an inner circumferential surface of the lower guide 250 in the vertical direction. Particularly, the lower combination grooves 252 may be downwardly formed from an upper end of the lower guide 250. The lower combination grooves 252 may be spaced apart from each other by a substantially uniform gap. Thus, a plurality of lower combination protrusions 254 may be formed between the lower combination grooves 252. The gap between the lower combination grooves 252 may be substantially the same as the gap between the upper combination grooves 222.

Thus, when the upper guide 220 may be downwardly moved toward the lower guide 250, the upper combination protrusions 224 may be inserted into the lower combination grooves 252 and the lower combination protrusions 254 may be inserted into the upper combination grooves 222 so that the upper guide 220 and the lower guide 250 may be firmly combined with each other. In contrast, when the upper guide 220 may be upwardly moved from the lower guide 250, the upper combination protrusions 224 may be released from the lower combination grooves 252 so that the upper guide 220 may be readily disassembled from the lower guide 250.

The lower cover 260 may have an annular shape. The lower cover 260 may have a diameter substantially the same as the diameter of the lower guide 250. The lower cooling passage 262 may be formed at the lower cover 260. Particularly, the lower cooling passage 262 may be formed on an upper surface of the lower cover 260 along a circumferential direction of the lower cover 260. That is, an upper surface of the lower cooling passage 262 may be upwardly exposed. When the lower cover 260 may be combined with the lower guide 250, the lower surface of the lower guide 250 may make contact with the upper surface of the lower cover 260. Thus, the upper surface of the lower cooling passage 262 may correspond to the lower surface of the lower guide 250.

Further, the lower guide 250 may include an inlet 264, a plurality of connection passage 268 and an outlet 266. The inlet 264 may be formed through an outer circumferential surface of the lower guide 250 in the horizontal direction. The refrigerant may be introduced into the lower guide 250 through the inlet 264. The inlet 264 may be connected to the upper cooling passage 232. Thus, the refrigerant may be supplied to the upper cooling passage 232. The connection passages 268 may be formed in the lower guide 250 along the vertical direction. The connection passages 268 may be connected between the upper cooling passage 232 and the lower cooling passage 262. Thus, the refrigerant in the upper cooling passage 232 may be introduced into the lower cooling passage 262 through the connection passage 268. The outlet 266 may be formed through an outer circumferential surface of the lower guide 250. The outlet 266 may be connected to the lower cooling passage 262. Thus, the refrigerant in the lower cooling passage 262 may be discharged from the lower guide 250 through the outlet 266.

The conductive adhesive 120 may be interposed between the reflector 110 and the frame 200. The conductive adhesive 120 may attach the reflector 110 to the frame 200. Particularly, the conductive adhesive 120 may attach the both ends of the blades 112 to the inner circumferential surface of the upper guide 220. Thus, the conductive adhesive 120 may have an annular shape configured to make contact with the outer circumferential surface of the reflector 110 and the inner circumferential surface of the upper guide 220.

In various example embodiments, the conductive adhesive 120 may include a material for allowing electron transportation and for blocking a refrigerant leakage. That is, the conductive adhesive 120 may have a sealing function for preventing the refrigerant leakage through the cooling passage. Further, the conductive adhesive 120 may include a conductive material for allowing the electron transportation. For example, the conductive adhesive 120 may include a conductive additive such as a carbon nanotube, a graphite, etc., but example embodiments are not limited thereto.

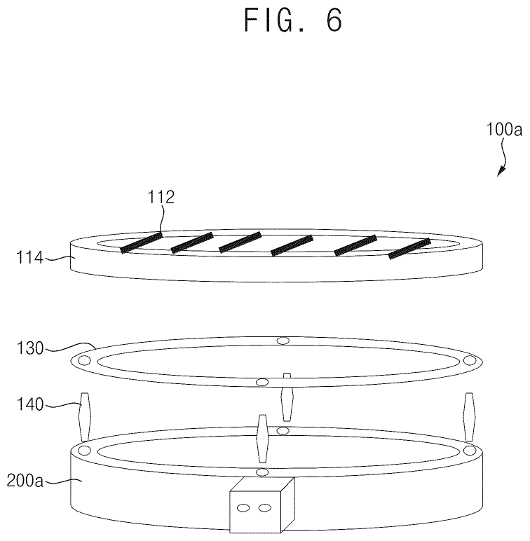

FIG. 6 is an exploded perspective view illustrating an ion neutralization module in accordance with various example embodiments.

Referring to FIG. 6, an ion neutralization module 100a of various example embodiments may include a plurality of blades 112, a blade ring 114, a frame 200a and a heat transfer type adhesive pad 130.

The blades 112 may be substantially the same as the blades in FIG. 2. Thus, any further illustrations with respect to the blades 112 may be omitted herein for brevity.

The blade ring 114 may have an annular shape configured to receive the blades 112. The blade ring 114 may fix the blades 112. Particularly, the both ends of the blades 112 may be fixed to an inner circumferential surface of the blade ring 114.

The frame 200a may be arranged under the blade ring 114. The frame 200a may have an annular shape. The frame 200a may have a diameter substantially the same as a diameter of the blade ring 114.

The heat transfer type adhesive pad 130 may be interposed between the blade ring 114 and the frame 200a to attach the blade ring 114 to the frame 200a. Particularly, the heat transfer type adhesive pad 130 may attach a lower surface of the blade ring 114 to an upper surface of the frame 200a.

In various example embodiments, the heat transfer type adhesive pad 130 may include a conductive material. Thus, electrons may be transported between the blade ring 114 and the frame 200a through the heat transfer type adhesive pad 130. The heat transfer type adhesive pad 130 may include a conductive additive such as a carbon nanotube, a graphite, etc., but example embodiments are not limited thereto.

Alternatively, the heat transfer type adhesive pad 130 may include a non-conductive material. In this case, the ion neutralization module 100a may further include at least one conductive plug 140.

The conductive plug 140 may be interposed between the blade ring 114 and the frame 200a. The conductive plug 140 may be electrically connected between the blade ring 114 and the frame 200a. Thus, electrons may be transported between the blade ring 114 and the frame 200a through the conductive plug 140.

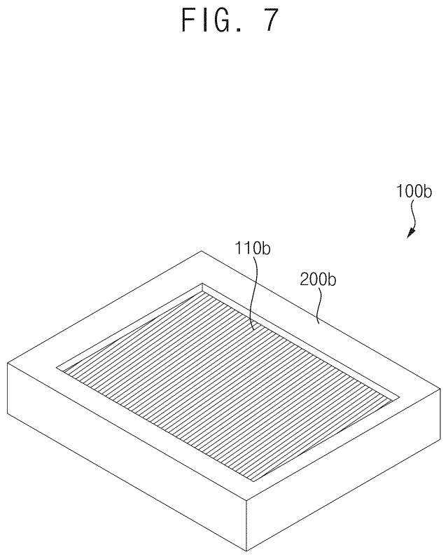

FIG. 7 is a perspective view illustrating an ion neutralization module in accordance with various example embodiments.

An ion neutralization module 100b of various example embodiments may include elements substantially the same as those of the ion neutralization module 100 in FIG. 2 except for blades and a frame. Thus, the same reference numerals may refer to the same elements and any further illustrations with respect to the same elements may be omitted herein for brevity.

Referring to FIG. 7, blades 110b of various example embodiments may have a rectangular shape. Thus, a frame 200b configured to support the blades 110b may have a rectangular frame shape.

According to various example embodiments, the ion neutralization module may include the detachable reflector and the frame so that optimal materials suitable for a semiconductor process may be applied to the reflector and the frame. Thus, a generation of a contaminant from the reflector may be suppressed. Further, a thermal deformation and/or a change of a surface roughness of the reflector at a high temperature may also be suppressed. As a result, the reflector may have improved neutralization efficiency.

The foregoing is illustrative of example embodiments and is not to be construed as limiting thereof. Although a few example embodiments have been described, those skilled in the art will readily appreciate that many modifications are possible in the example embodiments without droplet departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. An ion neutralization module comprising:
a reflector configured to neutralize an ion;
a frame configured to support the reflector; and
a conductive adhesive between the reflector and the frame to attach the reflector to the frame.

2. The ion neutralization module of claim 1, wherein the reflector comprises a material different from a material of the frame.

3. The ion neutralization module of claim 2, wherein the reflector comprises silicon or silicon carbide and the frame comprises at least one of molybdenum or tungsten.

4. The ion neutralization module of claim 1, wherein the conductive adhesive comprises a carbon nanotube or a graphite.

5. The ion neutralization module of claim 1, wherein the reflector comprises a plurality of blades.

6. The ion neutralization module of claim 1, wherein the frame comprises:
an upper frame configured to fix the reflector; and
a lower frame combined with the upper frame.

7. The ion neutralization module of claim 6, wherein the upper frame comprises:
an upper guide configured to support an outer circumferential surface of the reflector; and
an upper cover arranged on an upper surface of the upper guide, the upper cover including an upper cooling passage configured to flow refrigerant through the upper cooling passage.

8. The ion neutralization module of claim 7, wherein the upper guide comprises:
a plurality of upper combination grooves formed at an outer circumferential surface of the upper guide in a vertical direction; and
a plurality of upper combination protrusions formed between the plurality of the upper combination grooves.

9. The ion neutralization module of claim 8, wherein the lower frame comprises:
a lower guide configured to receive the upper frame; and
a lower cover arranged on a lower surface of the lower guide, the lower cover including a lower cooling passage configured to flow refrigerant through the lower cooling passage.

10. The ion neutralization module of claim 9, wherein the lower guide comprises:
a plurality of lower combination grooves formed at an inner circumferential surface of the lower guide in the vertical direction to receive the plurality of the upper combination protrusions; and
a plurality of lower combination protrusions formed between the plurality of lower combination grooves and inserted into the plurality of the upper combination grooves.

11. The ion neutralization module of claim 9, wherein the lower guide comprises:
an inlet connected to the upper cooling passage configured to receive the refrigerant;
a plurality of connection passages connected between the upper cooling passage and the lower cooling passage; and
an outlet connected to the lower cooling passage configured to discharge the refrigerant.

12. An ion neutralization module comprising:
a reflector including a plurality of blades configured to neutralize an ion;
a frame configured to support an outer circumferential surface of the reflector and to receive a refrigerant, the frame including a material different from a material of the reflector; and
a conductive adhesive interposed between the reflector and the frame to attach the reflector to the frame, the conductive adhesive configured to allow electron transportation and further configured to prevent leakage of the refrigerant,
wherein the frame comprises
an upper frame configured to fix the reflector, and
a lower frame combined with the upper frame.

13. The ion neutralization module of claim 12, wherein the upper frame comprises:
an upper guide configured to support the outer circumferential surface of the reflector; and
an upper cover arranged on an upper surface of the upper guide, the upper cover including an upper cooling passage configured to flow refrigerant through the upper cooling passage.

14. The ion neutralization module of claim 13, wherein the upper guide comprises:
a plurality of upper combination grooves formed at an outer circumferential surface of the upper guide in a vertical direction; and
a plurality of upper combination protrusions formed between the plurality of the upper combination grooves.

15. The ion neutralization module of claim 14, wherein the lower frame comprises:
a lower guide configured to receive the upper frame; and
a lower cover arranged on a lower surface of the lower guide, the lower cover including a lower cooling passage configured to flow refrigerant through the lower cooling passage.

16. The ion neutralization module of claim 15, wherein the lower guide comprises:
a plurality of lower combination grooves formed at an inner circumferential surface of the lower guide in the vertical direction to receive the plurality of the upper combination protrusions; and
a plurality of lower combination protrusions formed between the plurality of lower combination grooves and inserted into the plurality of the upper combination grooves.

17. The ion neutralization module of claim 15, wherein the lower guide comprises:
an inlet connected to the upper cooling passage configured to receive the refrigerant;
a plurality of connection passages connected between the upper cooling passage and the lower cooling passage; and
an outlet connected to the lower cooling passage configured to discharge the refrigerant.

18. An ion neutralization module comprising:
a plurality of blades configured to neutralize an ion;
a blade ring configured to fix both ends of the plurality of the blades;
a frame arranged under the blade ring, the frame including a material different from a material of the plurality of the blades; and
a heat transfer type adhesive pad interposed between the blade ring and the frame to attach the blade ring to the frame,
wherein the frame comprises
an upper frame configured to fix a reflector, and
a lower frame combined with the upper frame.

19. The ion neutralization module of claim 18, wherein the heat transfer type adhesive pad comprises a conductive material.

20. The ion neutralization module of claim 18, wherein the heat transfer type adhesive pad comprises a non-conductive material and a conductive plug configured to allow ion transportation, and the heat transfer type adhesive pad is between the blade ring and the frame.
